(19) United States
(12) Patent Application Publication
(10) Pub. No.: US 2012/0168794 A1
(43) Pub. Date: Jul. 5, 2012

(54) LIGHT-EMITTING DIODE STRUCTURE AND METHOD FOR MANUFACTURING THE SAME

(75) Inventors: Kuohui Yu, Tainan City (TW); Chienchun Wang, Tainan City (TW); Changhsin Chu, Tainan City (TW); Haoching Wu, Tainan City (TW)

(73) Assignee: CHI MEI LIGHTING TECHNOLOGY CORP., Tainan City (TW)

(21) Appl. No.: 13/081,793

(22) Filed: Apr. 7, 2011

(30) Foreign Application Priority Data
Dec. 29, 2010 (TW) 099146652

(51) Int. Cl. H01L 33/60

(52) U.S. Cl. 257/98; 438/27; 257/E33.072

(57) ABSTRACT

A light-emitting diode (LED) structure and a method for manufacturing the same. In one embodiment, the LED structure includes a carrying component, an LED chip, a first conductivity type electrode and a second conductivity type electrode. The carrying component includes a carrier, a sidewall disposed on the carrier and forms a carrying tank. The LED chip is fixed within the carrying tank and includes a first conductivity type semiconductor layer having a first region and a second region, an active layer and a second conductivity type semiconductor layer stacked in sequence. The LED chip further includes a second conductive finger disposed on the second semiconductor layer in the first region, and a first conductive finger disposed on the first semiconductor layer in the second region. The first electrode extends on the sidewall and the first conductive finger. The second electrode extends on the sidewall and the second conductive finger.

### CROSS-REFERENCE TO RELATED PATENT APPLICATION

This non-provisional application claims priority under 35 U.S.C. §119(a) on Patent Application No. 099146652 filed in Taiwan, R.O.C. on Dec. 29, 2010, the entire contents of which are hereby incorporated by reference.

### FIELD OF THE INVENTION

The present invention relates to a light-emitting device and a method for manufacturing the same, and more particularly to a light-emitting diode (LED) structure and a method for manufacturing the same.

### BACKGROUND OF THE INVENTION

In the techniques for manufacturing an LED device, with the development of the epitaxial technique and improvement of the chip manufacturing technique, the luminous efficiency of the LED is continuously increased. Therefore, a high luminance performance can be achieved even if the LED device is downsized.

FIG. 1 is a top view of a conventional LED. In the conventional LED 100, an n-type electrode 108 is disposed on an n-type semiconductor layer 102, and a p-type electrode 110 and a p-type conductive finger 112 are disposed on a p-type semiconductor layer 104. The p-type semiconductor layer 104 is the upper layer of a mesa 106 of an illuminant epitaxial structure. Therefore, the n-type electrode 108, the p-type electrode 110 and the p-type conductive finger 112 are all disposed on the body of the LED 100.

However, along with the downsizing of the LED, the ratio of the electrode area on the body of the LED to the area of the light emitting surface is greatly increased. Additionally, the electrode and the conductive finger have light shielding and absorbing effects. As a result, not only the effective light-emitting area of the LED is reduced, but also the luminous efficiency of the LED device is greatly reduced.

Therefore, a heretofore unaddressed need exists in the art to address the aforementioned deficiencies and inadequacies.

### SUMMARY OF THE INVENTION

Accordingly, in one aspect, the present invention is directed to an LED structure and a method for manufacturing the same. In one embodiment, an electrode of an LED chip is disposed on a sidewall of a chip body, so that the light absorbing and shielding phenomenon of the electrode can be avoided, thus providing a larger light emitting region and reducing the proportion of the absorbed light, and further effectively improving the light extraction efficiency of the LED device. As a result, the LED device can be further miniaturized to reduce the manufacturing cost.

In another aspect, the present invention is directed to an LED structure and a method for manufacturing the same. In one embodiment, a material having a refractive index between the refractive index of the semiconductor material layer and the refractive index of the packaging adhesive material may be used as the material of an extending sidewall, so that the extending sidewall becomes a optical waveguide structure for side emitting light of an active layer, thus increasing the surface area of the light emitting path of the side emitting light of the LED device and the light emitting region.

In yet another aspect, the present invention is directed to an LED structure and a method for manufacturing the same. In one embodiment, a scattering material may be added in the sidewall to enhance the multi-directional property of the light path, thus improving the overall light emitting efficiency of the LED device.

In a further aspect, the present invention is directed to an LED structure and a method for manufacturing the same. In one embodiment, a reflecting structure may be disposed on the carrier to reflect the light emitted by the active layer, thus further improving the light extraction efficiency of the LED device.

In an alternative aspect, the present invention is directed to an LED structure and a method for manufacturing the same. In one embodiment, a high thermal conductivity material may be used as the material of the carrier, thus improving the photoelectric conversion efficiency of the LED device, enhancing the stability of the device and extending the service life of the device.

In one aspect of the present invention, an LED structure is provided. The LED structure includes a carrying component, an LED chip, a first conductivity type electrode and a second conductivity type electrode. The carrying component includes a carrier and a sidewall, which is disposed on the carrier and forms a carrying tank on the carrier. The LED chip is fixed within the carrying tank. The LED chip includes a first conductivity type semiconductor layer, an active layer and a second conductivity type semiconductor layer stacked in sequence. The first conductivity type semiconductor layer has a first region and a second region. The LED chip further includes a second conductive finger disposed on the second conductivity type semiconductor layer in the first region, and a first conductive finger disposed on the first conductivity type semiconductor layer in the second region. The first conductivity type electrode extends on the sidewall and the first conductive finger. The second conductivity type electrode extends on the sidewall and the second conductive finger.

In one embodiment of the present invention, the first conductive finger and the second conductive finger are substantially at the same height as the sidewall.

In one embodiment of the present invention, the sidewall is lower than the first conductive finger and the second conductive finger.

In another embodiment of the present invention, the LED chip includes a first mesa and a second mesa separated from each other and respectively disposed on the first region and a part of the second region of the first conductivity type semiconductor layer, and the first mesa and the second mesa both include the first conductivity type semiconductor layer, the active layer and the second conductivity type semiconductor layer.

In yet another embodiment of the present invention, in the LED structure, the first conductive finger extends on a side surface and an upper surface of the second mesa.

In a further embodiment of the present invention, the materials of the carrier and the sidewall are different, and the material of the sidewall is an organic material or a polymer material.

In an alternative embodiment of the present invention, the carrying component is an integrally formed structure, and the sidewall has a bevel adjacent to the carrying tank. Furthermore, the carrier may include a through hole.

In yet another aspect of the present invention, a method for manufacturing an LED structure is further provided, which includes the following steps. An LED chip is provided. The LED chip includes a first conductivity type semiconductor layer, an active layer and a second conductivity type semiconductor layer stacked in sequence. The first conductivity type semiconductor layer has a first region and a second region. The LED chip further includes a second conductive finger disposed on the second conductivity type semiconductor layer in the first region, and a first conductive finger disposed on the first conductivity type semiconductor layer in the second region. The LED chip is fixed on a carrier. A sidewall is formed on the carrier to form a carrying tank for accommodating the LED chip. A first conductivity type electrode is formed by extending on the sidewall and the first conductive finger. A second conductivity type electrode is formed by extending on the sidewall and the second conductive finger.

In one embodiment of the present invention, the step of forming the sidewall includes: forming a transparent material layer covering the LED chip and the carrier; and planarizing the transparent material layer to expose the first conductive finger and the second conductive finger.

In another embodiment of the present invention, the planarization step includes: making the first conductive finger and the second conductive finger substantially the same height as the sidewall, or making the sidewall lower than the first conductive finger and the second conductive finger.

In yet another embodiment of the present invention, the carrier further includes a reflecting structure, and the reflecting structure and the sidewall are disposed on the same side of the carrier.

In a further aspect of the present invention, a method for manufacturing an LED structure is further provided, which includes the following steps. An LED chip is provided. The LED chip includes a first conductivity type semiconductor layer, an active layer and a second conductivity type semiconductor layer stacked in sequence. The first conductivity type semiconductor layer has a first region and a second region. The LED chip further includes a second conductive finger disposed on the second conductivity type semiconductor layer in the first region, and a first conductive finger disposed on the first conductivity type semiconductor layer in the second region. A carrying component is provided, in which the carrying component includes a carrier and a sidewall. The sidewall is disposed on the carrier and forms a carrying tank on the carrier. The LED chip is fixed within the carrying tank. A first conductivity type electrode is formed by extending on the sidewall and the first conductive finger. A second conductivity type electrode is formed by extending on the sidewall and the second conductive finger.

In one embodiment of the present invention, the method for manufacturing an LED structure further includes forming an adhesive layer on a surface of the carrying tank between the step of providing the carrying component and the step of fixing the LED chip within the carrying tank.

In another embodiment of the present invention, the carrier includes a through hole. Furthermore, the step of fixing the LED chip within the carrying tank includes: placing the LED chip into the carrying tank; and injecting an adhesive material into a clearance between the LED chip and the carrying tank.

In yet another embodiment of the present invention, the sidewall has a bevel adjacent to the carrying tank.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a top view of a conventional LED;

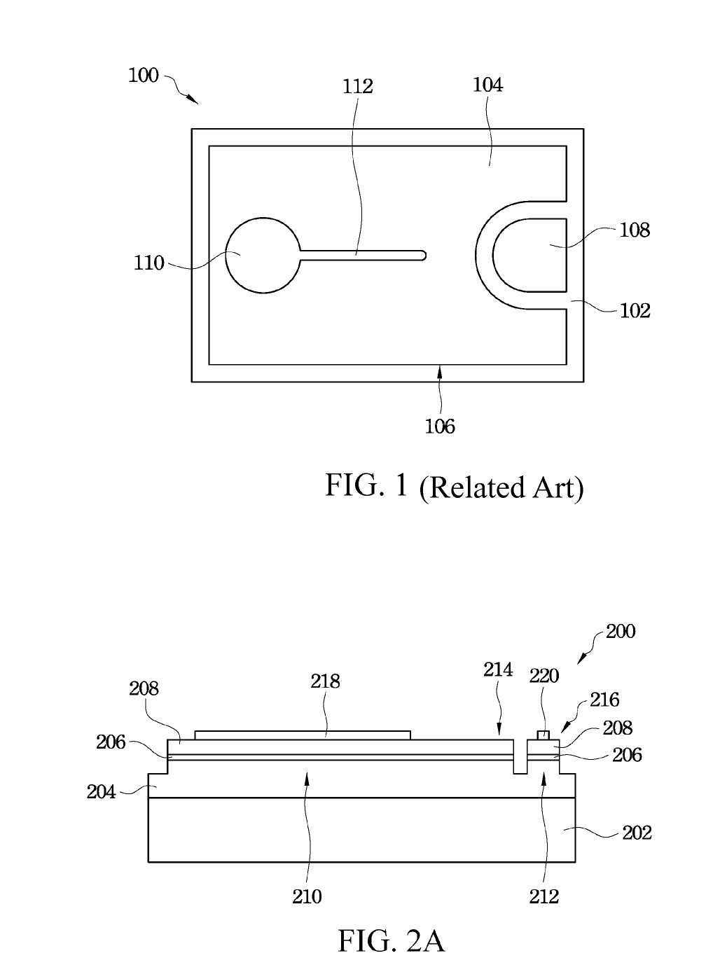

FIGS. 2A, 3A, 4A and 5A are sectional views illustrating processes of an LED structure according to one embodiment of the present invention;

FIGS. 2B, 3B, 4B and 5B are top views illustrating processes of an LED structure according to one embodiment of the present invention;

FIG. 2C is a three-dimensional view of the LED structure of FIG. 2A;

FIG. 3C is a top view of a plurality of LED chips disposed on a carrier according to another embodiment of the present invention;

FIGS. 6A, 7A and 7B, 9A and 10A are views illustrating processes of an LED structure according to another embodiment of the present invention, where FIG. 7B is a three-dimensional sectional view taken along a section line AA′ of the carrying component of FIG. 7A;

FIG. 6B is a top view of the LED structure of FIG. 6A;

FIG. 6C is a three-dimensional view of the LED structure of FIG. 6A;

FIG. 8 is a three-dimensional partial sectional view of a carrying component according to another embodiment of the present invention;

FIG. 9B is a sectional view of a carrying component and an LED chip device according to another embodiment of the present invention; and

FIG. 10B is a sectional view of an LED structure according to still another embodiment of the present invention.

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

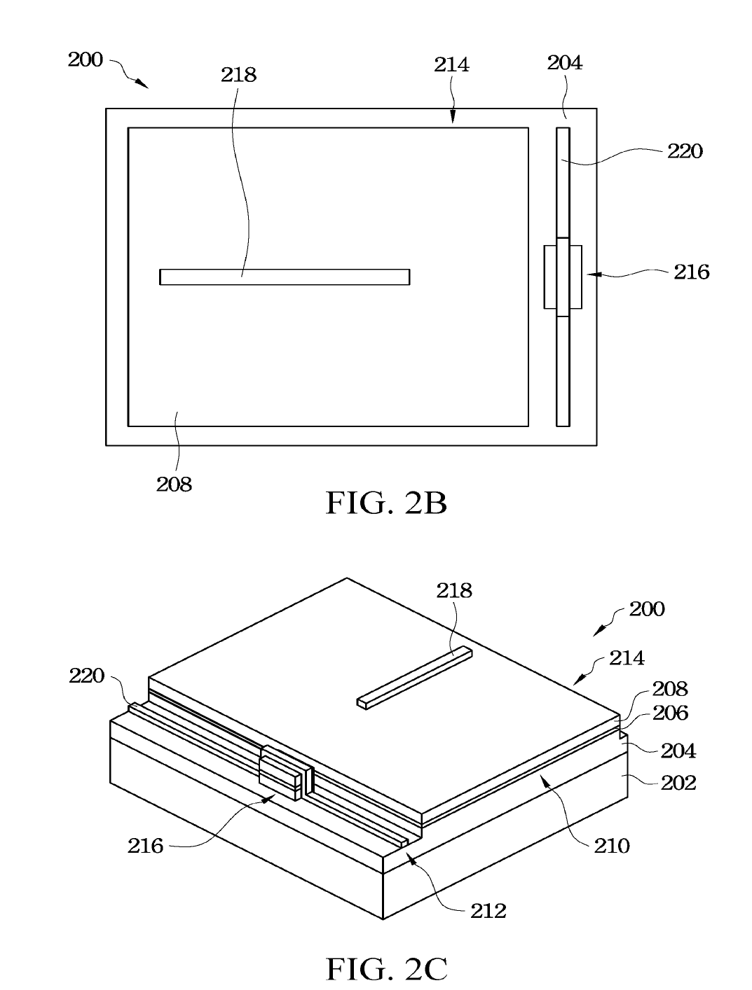

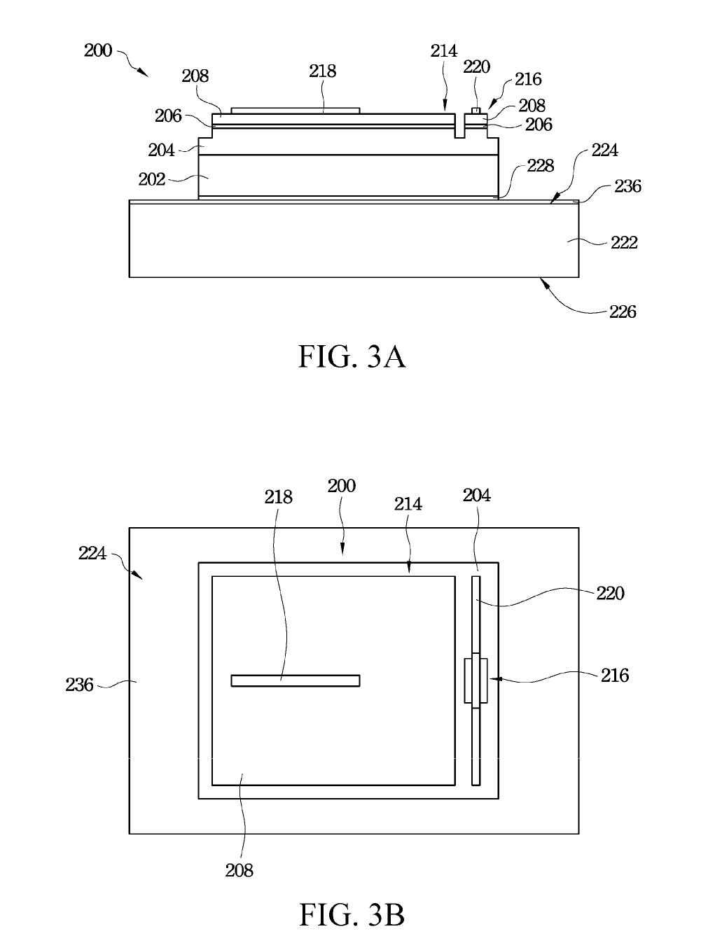

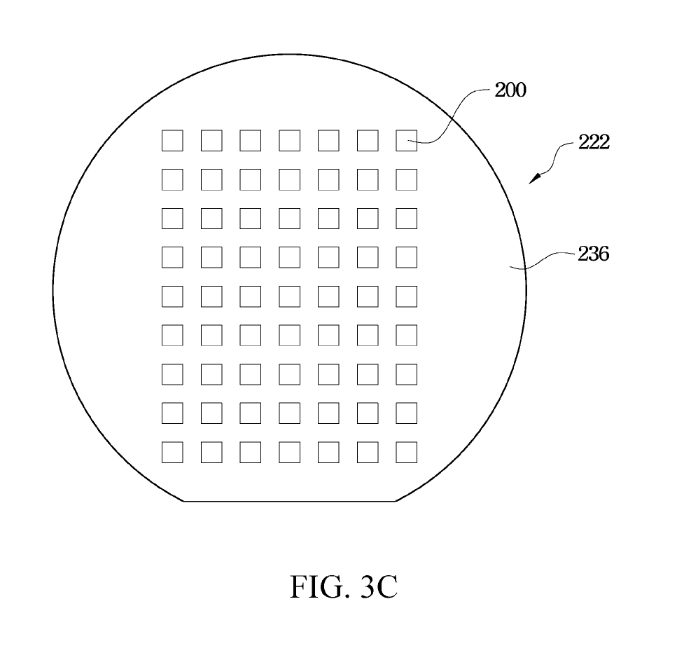

Please referring to FIGS. 2A, 3A, 4A, 5A, and FIGS. 2B, 3B, 4B, 5B, 2C. FIGS. 2A, 3A, 4A, 5A and FIGS. 2B, 3B, 4B, 5B are respectively sectional views and top views illustrating manufacturing processes of an LED structure according to one embodiment of the present invention. In this embodiment, in order to fabricate an LED structure, firstly, an LED chip 200 is provided. In an example, as shown in FIGS. 2A and 2C, the LED chip 200 may include a substrate 202 and a first conductivity type semiconductor layer 204, an active layer 206 and a second conductivity type semiconductor layer 208 stacked in sequence on the substrate 202. The first conductivity type and the second conductivity type are different conductivity types. For example, one of the first conductivity type and the second conductivity type is n-type, and the other type is p-type.

In this embodiment, as shown in FIGS. 2B and 2C, the LED chip 200 includes a structure of two mesas 214, 216, in which the two mesas 214, 216 are separated from each other. As shown in FIG. 2C, the mesas 214, 216 both include a stack structure formed by a part of the first conductivity type semiconductor layer 204, the active layer 206 and the second conductivity type semiconductor layer 208. The first conductivity type semiconductor layer 204 is mainly divided into a first region 210 and a second region 212. The mesas 214, 216 are respectively disposed on the first region 210 and a part of the second region 212 of the first conductivity type semiconductor layer 204, as shown in FIG. 2C. In one embodiment, the mesas 214, 216 are substantially at the same height.

As shown in FIGS. 2B and 2C, the LED chip 200 includes a first conductive finger 220 and a second conductive finger 218. The first conductive finger 220 extends on and covers a side surface and an upper surface of the mesa 216 and extends on a part of the second region 212 of the first conductivity type semiconductor layer 204, as shown in FIG. 2C. The second conductive finger 218 is disposed on the mesa 214. As shown in FIG. 2B, in one embodiment, the first conductive finger 220 and the second conductive finger 218 may be disposed in a manner of extending in directions substantially perpendicular to each other, so as to facilitate current spreading. In one embodiment, the thickness of the LED chip 200 without the first conductive finger 220 and the second conductive finger 218 is between about 5 μm and 400 μm.

In a general application, when the second conductivity type semiconductor layer 208 is p-type, due to the poor conductivity of the p-type semiconductor layer, normally a transparent conductive layer (not shown) such as an indium tin oxide (ITO) layer is additionally disposed on the second conductivity type semiconductor layer 208, so that the transparent conductive layer is between the second conductivity type semiconductor layer 208 and the second conductive finger 218 to provide a current spreading effect.

Next, a carrier 222 is provided. In one embodiment, the material of the carrier 222 may be a transparent material, e.g. sapphire, SiC and glass. In another embodiment, the material of the carrier 222 may be a high thermal conductivity material, e.g. a metal, silicone, ceramic and AlN. The carrier 222 has two opposite surfaces 224, 226. In one embodiment, the carrier 222 may include a reflecting structure 236, in which the reflecting structure 236 is disposed on the surface 224 of the carrier 222. The reflecting structure 236 may be a metal layer, e.g. Al layer or Ag layer. The reflecting structure 236 may also be a Distributed Bragg Reflector (DBR), in which the material of the DBR for example may include SiO₂, TiO₂ and Al₂O₃.

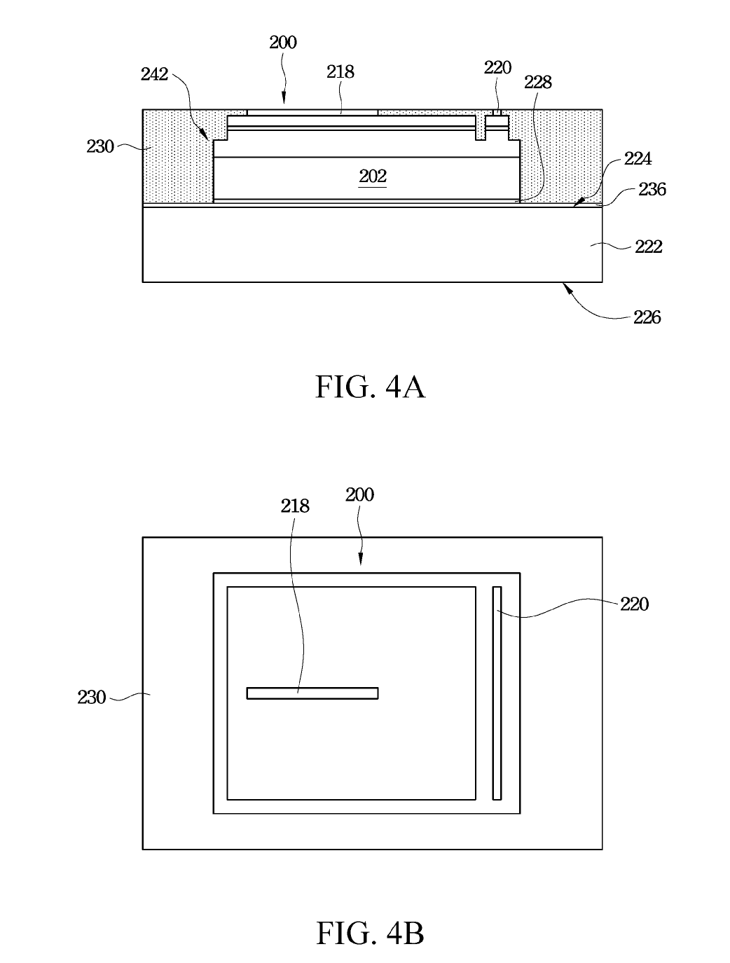

Then, as shown in FIGS. 3A and 3B, an adhesive layer 228 is used to fix the LED chip 200 on the surface 224 of the carrier 222. The material of the adhesive layer 228 may be for example a transparent adhesive material, a metal material or a silver paste. In another embodiment, the LED chip 200 may also be fixed on the surface 224 of the carrier 222 by bonding.

In one embodiment, according to the product requirements, pattern structures (not shown) may be further disposed on the surface 224 and/or the surface 226 of the carrier 222, thus changing the transmission direction of light. The pattern structures may be for example array structures, quasi-array structures or irregular roughened structures.

Referring to FIG. 3C, in practical manufacturing, firstly, a plurality of LED chips 200 are adhered on the reflecting structure 236 on the carrier 222 having a larger area, and the LED chips 200 are spaced from each other by a predetermined distance. Afterwards, all the LED chips 200 on the carrier 222 are subjected to the follow-up processes at the same time. After all the processes are completed, a scribing and breaking process is performed to separate the LED chips 200, and thus the fabrication of a plurality of LED structures 240 is finished (referring to FIGS. 5A and 5B firstly).

After the LED chip 200 is fixed on the carrier 222, as shown in FIGS. 4A and 4B, a sidewall 230 is formed on the surface 224 of the carrier 222, in which the sidewall 230 is disposed surrounding the LED chip 200. The sidewall 230 and the carrier 222 constitute a carrying component, in which the sidewall 230 defines a carrying tank 242 on the surface 224 of the carrier 222, and the LED chip 200 is accommodated in the carrying tank 242. In this embodiment, the sidewall 230 and the carrier 222 are made of different materials.

In one embodiment, in order to fabricate the sidewall 230, firstly, a non-conductive transparent material layer (only the sidewall 230 is shown) may be formed on the LED chip 200 and the carrier 222 by coating and covers the entire LED chip 200. The material of the transparent material layer may be an organic material or a polymer material, e.g. spin on glass (SOG). Then, the transparent material layer is planarized by etching or polishing such as Chemical Mechanical Polishing (CMP), so that the transparent material layer has a planarized surface, and the first conductive finger 220 and the second conductive finger 218 of the LED chip 200 are exposed. Thus, the fabrication of the sidewall 230 of the carrying component is finished, as shown in FIG. 4A. Since the sidewall 230 and the reflecting structure 236 are both disposed on the surface 224 of the carrier 222, the reflecting structure 236 and the sidewall 230 are disposed on the same side of the carrier 222. Furthermore, the LED chip 200 may be disposed in the same plane as the sidewall 230, that is, also disposed on the surface of the carrier 222.

In one embodiment, as shown in FIG. 4A, after the planarization step, the first conductive finger 220 and the second conductive finger 218 are substantially at the same height as the sidewall 230, for facilitating the follow-up fabrication of electrodes. In another embodiment, under the influence of the manufacturing process tolerance of the planarization step, the sidewall 230 may be slightly lower than the first conductive finger 220 and the second conductive finger 218.

In some embodiments, according to the product requirements, a light extraction enhancement material may be added in the transparent material of the sidewall 230. The light extraction enhancement material may be a material capable of changing a refractive index of the sidewall 230, e.g. a material capable of enhancing the light extraction efficiency of the LED chip 200 after packaging. Therefore, in an example, the light extraction enhancement material enables the refractive index of the sidewall 230 to be between the refractive index of the LED chip 200 and the refractive index of a packaging adhesive material to be disposed subsequently. The light extraction enhancement material may also be a material capable of changing a light path of light in the sidewall 230, e.g. particles made of a high polymer or resin, in which the particles may have multiple size, e.g. micron-sized particles or nano-sized particles. When the light emitted by the active layer is irradiated on the particles, the light path may change, thus enhancing the light extraction efficiency.

Then, the first conductivity type electrode 234 and the second conductivity type electrode 232 are patterned by for example lithography, plating and lift-off. As shown in FIG. 5B, the first conductivity type electrode 234 includes a finger part 238. A main body of the first conductivity type electrode 234 for wire bonding is disposed on the sidewall 230 and is connected to the first conductive finger 220 by the finger part 238. Therefore, as shown in FIG. 5A, the first conductivity type electrode 234 extends on the sidewall 230 and the first conductive finger 220, and is electrically connected to the first conductive finger 220.

On the other hand, the second conductivity type electrode 232 also includes a finger part 237. A main body of the second conductivity type electrode 232 for wire bonding is also disposed on the sidewall 230 and is connected to the second conductive finger 218 by the finger part 237. Therefore, as shown in FIG. 5A, the second conductivity type electrode 232 extends on the sidewall 230 and the second conductive finger 218, and is electrically connected to the second conductive finger 218. After the first conductivity type electrode 234 and the second conductivity type electrode 232 are formed, the fabrication of the LED structure 240 is completed.

In the LED structure 240, since the first conductivity type electrode 234 and the second conductivity type electrode 232 of the LED chip 200 are both disposed on the sidewall 230 outside of the body of the LED chip 200, the light absorbing and light shielding phenomenon of the first conductivity type electrode 234 and the second conductivity type electrode 232 can be avoided. Therefore, the LED structure 240 has a larger light emitting region and the proportion of the absorbed light is reduced, thus effectively improving the light extraction efficiency of the LED structure 240. The LED chip 200 can be further miniaturized to reduce the manufacturing cost.

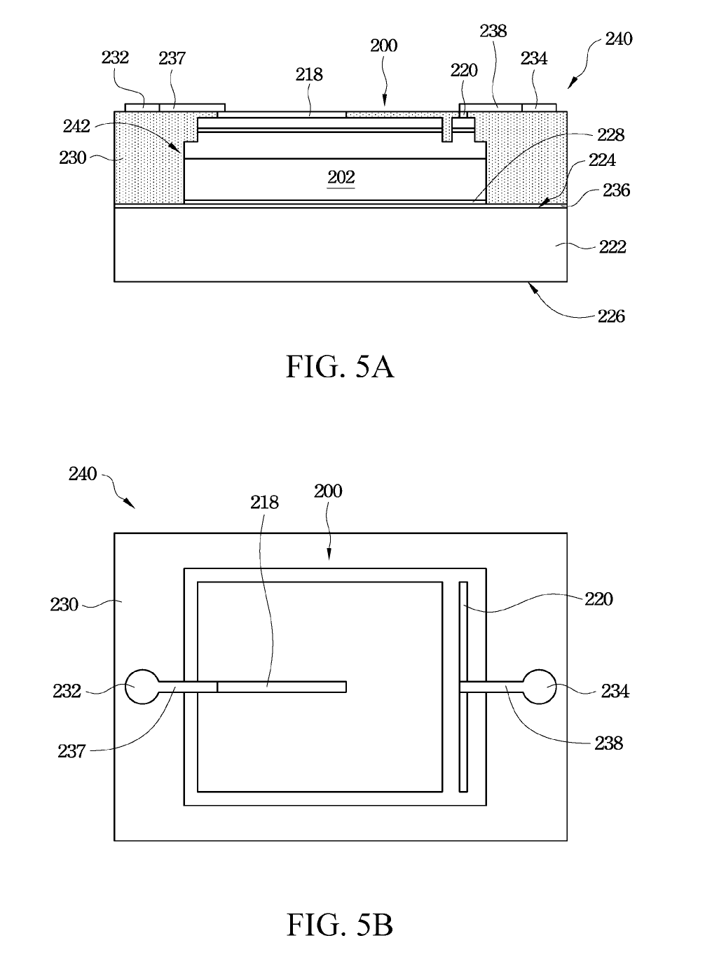

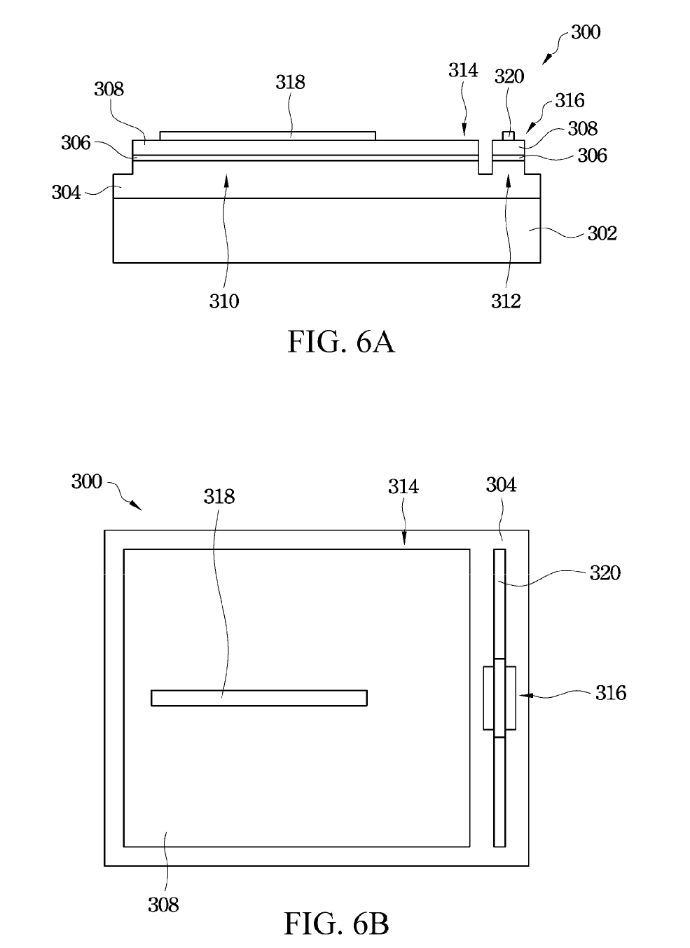

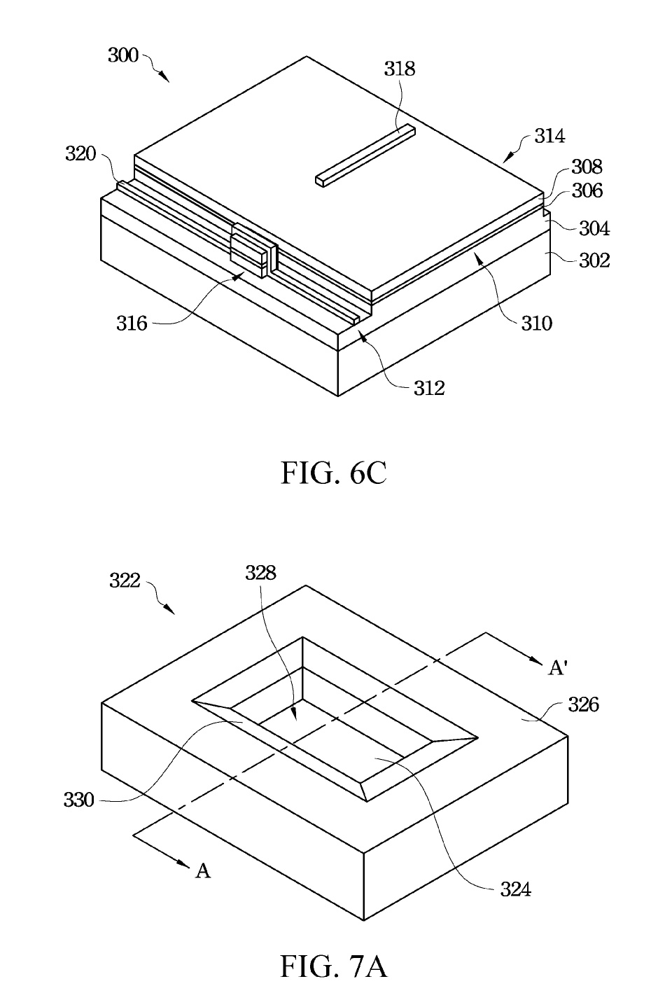

The carrying component of the present invention may also be an integrally formed architecture. FIGS. 6A, 7A and 7B, 9A and 10A are views illustrating manufacturing processes of an LED structure according to another embodiment of the present invention. FIG. 7B is a three-dimensional sectional view taken along a section line AA′ of the carrying component of FIG. 7A. In this embodiment, in order to fabricate an LED structure, firstly, an LED chip 300 is provided. In an example, as shown in FIGS. 6A and 6C, the LED chip 300 may include a substrate 302 and a first conductivity type semiconductor layer 304, an active layer 306 and a second conductivity type semiconductor layer 308 stacked in sequence on the substrate 302. The first conductivity type and the second conductivity type are different conductivity types. For example, one of the first conductivity type and the second conductivity type is n-type, and the other is p-type.

In one embodiment, as shown in FIGS. 6B and 6C, the LED chip 300 includes two mesas 314, 316, in which the two mesas 314, 316 are separated from each other. As shown in FIG. 6C, the mesas 314, 316 both include a stack structure formed by a part of the first conductivity type semiconductor layer 304, the active layer 306 and the second conductivity type semiconductor layer 308. The first conductivity type semiconductor layer 304 includes a first region 310 and a second region 312. The mesas 314, 316 are respectively disposed on the first region 310 and a part of the second region 312 of the first conductivity type semiconductor layer 304, as shown in FIG. 6C. In one embodiment, the mesas 314, 316 are substantially at the same height.

The LED chip 300 includes a first conductive finger 320 and a second conductive finger 318. The first conductive finger 320 extends on and covers a side surface and an upper surface of the mesa 316 and extends on a part of the second region 312 of the first conductivity type semiconductor layer 304, as shown in FIG. 6C. The second conductive finger 318 is disposed on the mesa 314. In one embodiment, as shown in FIG. 6B, the extending directions of the first conductive finger 320 and the second conductive finger 318 are substantially perpendicular to each other, so as to facilitate current spreading. In one embodiment, the thickness of the LED chip 300 without the first conductive finger 320 and the second conductive finger 318 is between about 5 μm and 400 μm.

In a general application, when the second conductivity type semiconductor layer 308 is p-type, due to the poor conductivity of the p-type semiconductor layer, normally a transparent conductive layer (not shown) such as an ITO layer is additionally disposed on the second conductivity type semiconductor layer 308, so that the transparent conductive layer is between the second conductivity type semiconductor layer 308 and the second conductive finger 318 to provide a current spreading effect.

Then, a carrying component 322 is provided. As shown in FIG. 7A, the carrying component 322 may include a carrier 324 and a sidewall 326. The sidewall 326 is fixed on a surface of the carrier 324 and defines a carrying tank 328 on the carrier 324. The LED chip 300 may be accommodated in the carrying tank 328. In this embodiment, the carrying component 322 is an integrally formed structure. Furthermore, the carrier 324 and the sidewall 326 of the carrying component 322 may be made of the same material. In one embodiment, the material of the carrying component 322 may be a transparent insulating material, e.g. sapphire, resin and glass. In another embodiment, the material of the carrying component 322 may be a high thermal conductivity insulating material, e.g. a ceramic material.

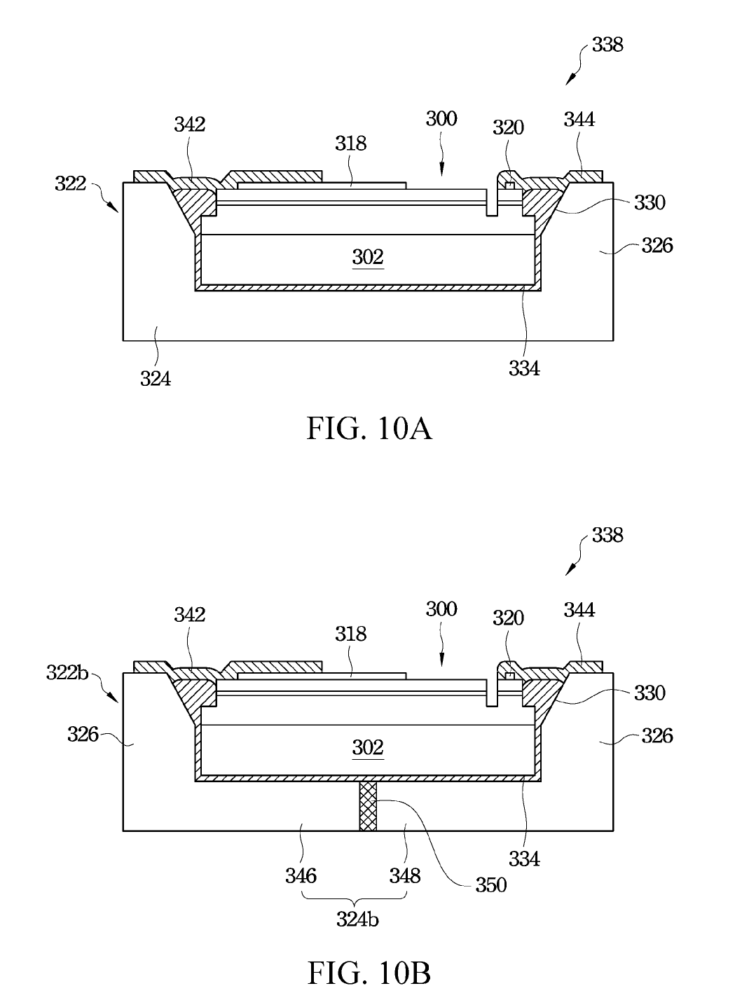

In other embodiments, referring to FIG. 10B, the carrier 324b of the carrying component 322b may also include two independent parts 346, 348. The two parts 346, 348 are bonded by an insulating material 350 and therefore are electrically isolated. The two parts 346, 348 are respectively adjacent to the first conductive finger 320 and the second conductive finger 318, and each of the parts 346, 348 has the sidewall 326. At this time, the material of the two parts 346, 348 of the carrying component 322b may adopt a high thermal conductivity conductive material such as a metal material to enhance the heat dissipation effect of the LED device. In these embodiments, referring to FIG. 10B, the first conductivity type electrode 344 only extends on the first conductive finger 320 and the sidewall 326 of the part 348 adjacent to the first conductive finger 320. The second conductivity type electrode 342 only extends on the second conductive finger 318 and the sidewall 326 of the part 346 adjacent to the second conductive finger 318.

In some embodiments, according to the product requirements, a light extraction enhancement material may be added in the material of the carrying component 322. The light extraction enhancement material may be a material capable of changing a refractive index of the carrying component 322, e.g. a material capable of enhancing the light extraction efficiency of the LED chip 300 after packaging. Therefore, in an example, the light extraction enhancement material enables the refractive index of the carrying component 322 to be between the refractive index of the LED chip 300 and the refractive index of a packaging adhesive material to be disposed subsequently. The light extraction enhancement material may also be a material capable of changing a light path of light in the sidewall 326 of the carrying component 322, e.g. particles made of a high polymer or resin, in which the particles may have multiple size ratings, e.g. micron-sized particles or nano-sized particles. When the light emitted by the active layer is irradiated on the particles, the light path may change, thus enhancing the light extraction efficiency.

Furthermore, according to the product requirements, pattern structures (not shown) may be further disposed on a bottom surface of the carrier 324 of the carrying component 322 or a bottom surface of the carrying tank 328, thus changing the transmission direction of light. The pattern structures may be for example array structures, quasi-array structures or irregular roughened structures. In addition, according to the manufacturing process requirements, the sidewall 326 may be designed with a bevel 330, in which the bevel 330 is adjacent to the carrying tank 328 and is inclined towards the carrying tank 328.

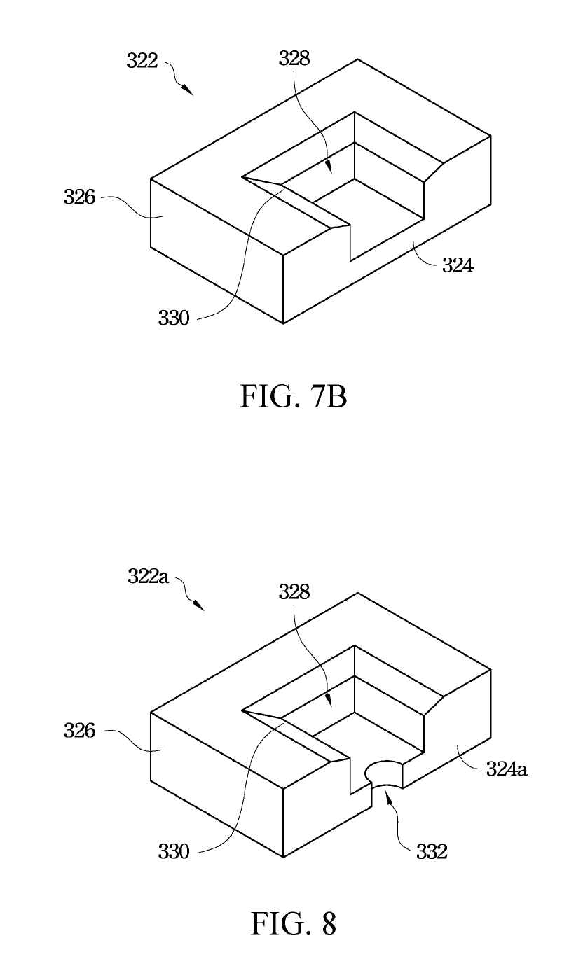

As shown in FIG. 7A, in one embodiment, the carrier 324 of the carrying component 322 is a flat-plate structure and is not designed with any through hole. However, as shown in FIG. 8, in other embodiments, the carrier 324a of the carrying component 322a is not an intact flat-plate structure, but has a through hole 332 formed through the carrier 324a.

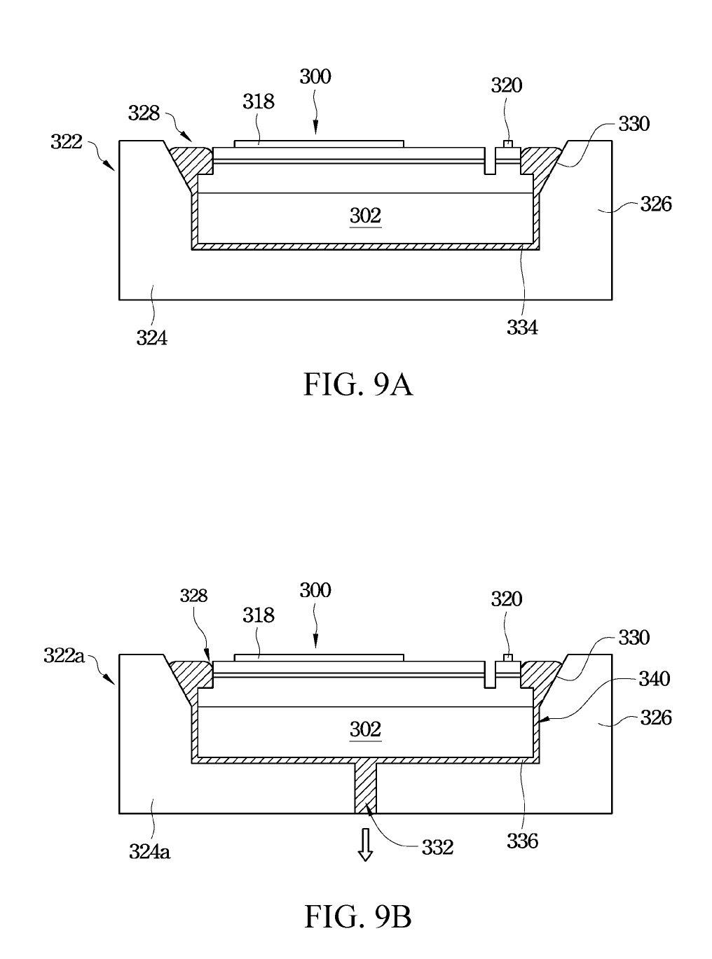

Then, the LED chip 300 is fixed within the carrying tank 328 of the carrying component 322 or 322a. In one embodiment, referring to FIG. 9A, firstly, an adhesive layer 334 is coated on a surface of the carrying tank 328 of the carrying component 322. Next, the LED chip 300 is placed into the carrying tank 328 by a robotic arm. Since the sidewall 326 of the carrying component 322 has the bevel 330, the process margin for placing the LED chip into the carrying tank 328 by the robotic arm can be increased, thus effectively improving the process reliability. The LED chip 300 can be stably fixed within the carrying component 322 by the adhesive layer 334.

In another embodiment of fixing the LED chip 300, referring to FIG. 9B, firstly, the LED chip 300 is placed into the carrying tank 328 of the carrying component 322a by for example the robotic arm. Likewise, since the sidewall 326 of the carrying component 322a has the bevel 330, the process margin for placing the LED chip into the carrying tank 328 by the robotic arm can be increased, thus effectively improving the process reliability. Next, an adhesive material 336 is injected into a clearance 340 between the LED chip 300 and the carrying tank 328. At this time, the adhesive material 336 is removed by a negative pressure through the through hole 332 of the carrier 324a to enhance the fluidity of the adhesive material 336, thus achieving a more uniform distribution of the adhesive material 336 in the carrying tank 328. After the adhesive material 336 is uniformly distributed between the carrying tank 328 and the LED chip 300, the adhesive material 336 filling up the through hole 332 and the space between the carrying tank 328 and the LED chip 300 is solidified. The LED chip 300 can be stably fixed within the carrying component 322a by the adhesive material 336. Here, the adhesive material 336 is for example a transparent adhesive material, a metal material or a silver paste. In another embodiment, the through hole 332 may also be filled up by a material different from the adhesive material 336, e.g. epoxy or silicone.

After the LED chip 300 is fixed within the carrying tank 328 of the carrying component 322, the sidewall 326 is disposed surrounding the LED chip 300. In one embodiment, as shown in FIG. 9A or 9B, the first conductive finger 320 and the second conductive finger 318 are substantially at the same height as the sidewall 326, for facilitating the follow-up fabrication of electrodes. In another embodiment, the sidewall 326 may be slightly lower than the first conductive finger 320 and the second conductive finger 318.

Then, as shown in FIG. 10A, the first conductivity type electrode 344 and the second conductivity type electrode 342 are patterned by, for example, lithography, plating and lift-off. Similar to the above embodiment, the first conductivity type electrode 344 may also include a finger part (not shown). A main body of the first conductivity type electrode 344 for wire bonding is disposed on the sidewall 326 and is connected to the first conductive finger 320 by the finger part. Therefore, the first conductivity type electrode 344 extends on the sidewall 326 and the first conductive finger 320 and is electrically connected to the first conductive finger 320.

Likewise, the second conductivity type electrode 342 includes a finger part (not shown). A main body of the second conductivity type electrode 342 for wire bonding is disposed on the sidewall 326 and is connected to the second conductive finger 318 by the finger part. Therefore, the second conductivity type electrode 342 extends on the sidewall 326 and the second conductive finger 318 and is electrically connected to the second conductive finger 318. After the first conductivity type electrode 344 and the second conductivity type electrode 342 are formed, the fabrication of the LED structure 338 is completed.

It can be seen from the above embodiments, an advantage of the present invention, among other things, lies in that the electrode of the LED chip is disposed on the sidewall outside the chip body in the present invention. Therefore, the light absorbing and light shielding phenomenon of the electrode can be avoided, thus providing a larger light emitting region and reducing the proportion of the absorbed light, and further effectively improving the light extraction efficiency of the LED device, and the LED chip can be further miniaturized so as to reduce the manufacturing cost.

It can be seen from the above embodiments, another advantage of the present invention, among other things, lies in that a material having a refractive index between the refractive index of the semiconductor material layer and the refractive index of the packaging adhesive material may be used as the material of the extending sidewall in the present invention, so that the extending sidewall becomes a optical waveguide structure for side light of the active layer, thus increasing the surface area of the light emitting path of the side light of the LED device and the light emitting region.

It can be seen from the above embodiments, yet another advantage of the present invention, among other things, lies in that a scattering material may be added in the sidewall in the present invention to enhance the multi-directional property of the light path, thus improving the overall light emitting efficiency of the LED device.

It can be seen from the above embodiments, a further advantage of the present invention, among other things, lies in that according to the LED structure and the method for manufacturing the same of the present invention, a reflecting structure may be disposed on the carrier to reflect the light emitting by the active layer, thus further improving the light extraction efficiency of the LED device.

It can be seen from the above embodiments, an alternative advantage of the present invention, among other things, lies in that according to the LED structure and the method for manufacturing the same of the present invention, a high thermal conductivity material may be used as the material of the carrier, thus improving the photoelectric conversion efficiency of the LED device, enhancing the stability of the device and extending the service life of the device.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) structure, comprising:
a carrying component having a carrier and a sidewall, wherein the sidewall is disposed on the carrier and forms a carrying tank on the carrier;
an LED chip, fixed within the carrying tank, wherein the LED chip has a first conductivity type semiconductor layer, an active layer and a second conductivity type semiconductor layer stacked in sequence, wherein the first conductivity type semiconductor layer has a first region and a second region, and wherein the LED chip further comprises:
a second conductive finger, disposed on the second conductivity type semiconductor layer in the first region; and
a first conductive finger, disposed on the first conductivity type semiconductor layer in the second region;
a first conductivity type electrode, extending on the sidewall and the first conductive finger; and
a second conductivity type electrode, extending on the sidewall and the second conductive finger.

2. The LED structure according to claim 1, wherein the LED chip further comprises a first mesa and a second mesa separated from each other and respectively disposed on the first region and a part of the second region of the first conductivity type semiconductor layer, the first mesa and the second mesa both comprise the first conductivity type semiconductor layer, the active layer and the second conductivity type semiconductor layer.

3. The LED structure according to claim 2, wherein the first conductive finger extends on a side surface and an upper surface of the second mesa.

4. The LED structure according to claim 1, wherein the first conductive finger and the second conductive finger are substantially at the same height as the sidewall.

5. The LED structure according to claim 1, wherein the sidewall is lower than the first conductive finger and the second conductive finger.

6. The LED structure according to claim 1, wherein the sidewall comprises a light extraction enhancement material, and the light extraction enhancement material is a material capable of changing a refractive index of the sidewall or a material capable of changing a light path of light in the sidewall.

7. The LED structure according to claim 1, further comprising a reflecting structure disposed on the carrier, wherein the reflecting structure and the sidewall are disposed on the same side of the carrier.

8. The LED structure according to claim 1, wherein the carrying component is an integrally formed structure, and the sidewall has a bevel adjacent to the carrying tank.

9. The LED structure according to claim 1, wherein the carrying component is an integrally formed structure, and the carrier comprises a through hole.

10. A method for manufacturing a light-emitting diode (LED) structure, comprising:
providing an LED chip, wherein the LED chip comprises a first conductivity type semiconductor layer, an active layer and a second conductivity type semiconductor layer stacked in sequence, the first conductivity type semiconductor layer has a first region and a second region, the LED chip further comprises:
a second conductive finger, disposed on the second conductivity type semiconductor layer in the first region; and
a first conductive finger, disposed on the first conductivity type semiconductor layer in the second region;
fixing the LED chip on a carrier;
forming a sidewall on the carrier to form a carrying tank for accommodating the LED chip;
forming a first conductivity type electrode extending on the sidewall and the first conductive finger; and
forming a second conductivity type electrode extending on the sidewall and the second conductive finger.

11. The method for manufacturing an LED structure according to claim 10, wherein the LED chip comprises a first mesa and a second mesa separated from each other and respectively disposed on the first region and a part of the second region of the first conductivity type semiconductor layer, the first mesa and the second mesa both comprise the first conductivity type semiconductor layer, the active layer and the second conductivity type semiconductor layer.

12. The method for manufacturing an LED structure according to claim 10, wherein the step of forming the sidewall comprises:
forming a transparent material layer covering the LED chip and the carrier; and
planarizing the transparent material layer to expose the first conductive finger and the second conductive finger.

13. The method for manufacturing an LED structure according to claim 12, wherein the material of the transparent material layer is an organic material or a polymer material.

14. The method for manufacturing an LED structure according to claim 12, wherein the planarization step comprises making the first conductive finger and the second conductive finger be substantially at the same height as the sidewall.

15. The method for manufacturing an LED structure according to claim 12, wherein the planarization step comprises making the sidewall be lower than the first conductive finger and the second conductive finger.

16. The method for manufacturing an LED structure according to claim 10, wherein the carrier further comprises a reflecting structure, and the reflecting structure and the sidewall are disposed on the same side of the carrier.

17. A method for manufacturing a light-emitting diode (LED) structure, comprising:
providing an LED chip, wherein the LED chip comprises a first conductivity type semiconductor layer, an active layer and a second conductivity type semiconductor layer stacked in sequence, the first conductivity type semiconductor layer has a first region and a second region, the LED chip further comprises:
a second conductive finger, disposed on the second conductivity type semiconductor layer in the first region; and
a first conductive finger, disposed on the first conductivity type semiconductor layer in the second region;
providing a carrying component, wherein the carrying component comprises a carrier and a sidewall, and the sidewall is disposed on the carrier and forms a carrying tank on the carrier;
fixing the LED chip within the carrying tank;
forming a first conductivity type electrode extending on the sidewall and the first conductive finger; and
forming a second conductivity type electrode extending on the sidewall and the second conductive finger.

18. The method for manufacturing an LED structure according to claim 17, wherein the LED chip comprises a first mesa and a second mesa separated from each other and respectively disposed on the first region and a part of the second region of the first conductivity type semiconductor layer, the first mesa and the second mesa both comprise the first conductivity type semiconductor layer, the active layer and the second conductivity type semiconductor layer.

19. The method for manufacturing an LED structure according to claim 17, further comprising forming an adhesive layer on a surface of the carrying tank between the step of providing the carrying component and the step of fixing the LED chip within the carrying tank.

20. The method for manufacturing an LED structure according to claim 17, wherein the carrier comprises a through hole, and the step of fixing the LED chip within the carrying tank comprises:
placing the LED chip into the carrying tank; and
injecting an adhesive material into a clearance between the LED chip and the carrying tank.

21. The method for manufacturing an LED structure according to claim 17, wherein the sidewall has a bevel adjacent to the carrying tank.
